(19) United States
(12) Patent Application Publication
(10) Pub. No.: US 2006/0102225 A1
(43) Pub. Date: May 18, 2006

(54) Base assembly having a plurality of solar powered illuminators for simultaneously illumination

(76) Inventor: Chih-Pang Chou, Taipei City (TW)

Correspondence Address: TROXELL LAW OFFICE PLLC;SUITE 1404, 5205 LEESBURG PIKE, FALLS CHURCH, VA, 22041, US

(21) Appl. No.: 10/986,012

(22) Filed: Nov. 12, 2004

(51) Int. Cl. H01L 25/00

(52) U.S. Cl. 136/244; 136/251; 136/293

(57) ABSTRACT

The present invention relates to a base assembly having a plurality of solar powered illuminators, characterized in that in each of the solar powered bases, at least one illumination device is controlled by a sensor and a timing device therein to illuminate at a predetermined interval for the purpose of saving energy; and by signals transmitting through transceivers, all the solar powered bases can illuminate simultaneously.

### BACKGROUND OF THE INVENTION

1. Field of the Invention

The present invention relates to a solar powered base assembly having a plurality of solar powered illuminators having transceivers and sensors, and more particularly, to a solar powered base assembly being able to simultaneously illuminate in the evening or in the dark place through signals transmission of the transceivers and sensors.

2. Description of the Prior Art

In this electrification era, our lives have been tied up with electrical equipments; people's lives have not been limited by the daylight. In today's modern world, electricity and power networks make people enable to work anytime and anywhere, but with electrical equipments more and more popular, how to save power in use of them becomes more and more important. Today public illumination devices generally have been established well in the aspects of types and quantity. However, high brightness illumination devices waste much energy in some place where it is not necessary for such high brightness, so some low brightness illumination devices which can save energy has been disclosed.

Most public illumination devices for low brightness are outside electrically connected to alternating current source, and usually waste energy for unnecessary illumination, and if the illumination devices are located in humid surroundings, there may be a danger of electric leakage. Therefore, there is a type of illumination device that uses solar energy as its power source providing safety and saving energy. For example, a solar powered floor brick provided with a solar panel for collection of solar energy so as to convert the solar energy to electric energy to charge at least one rechargeable battery. When sunlight is too little to be converted, the rechargeable battery automatically discharges electricity for the need of illumination of an illumination device. Once the solar panel cannot capture enough sunlight, the illumination device starts illuminating, even if there is nobody nearby. So, the solar powered floor brick still wastes power and cannot save energy much more effectively.

### SUMMARY OF THE INVENTION

The invention relates a base assembly having a plurality of solar powered illuminators for simultaneously illumination. In each solar powered base, at least one rechargeable battery, attached in the base, is respectively electrically connected to a solar panel; a transceiver; and at least one first illumination device which is electrically connected to the transceiver. In the daylight, the solar panel collects solar energy, converts the solar energy to electric energy, and charges the rechargeable battery. In the evening, when the sunlight is too little to be collected by the solar panel, the rechargeable battery discharges electricity for elements in the base; and when one induces the sensing of the sensor, the sensor sends a signal to the at least one first illumination device immediately to drive it illuminating, and through the transceiver, the sensor sends another signal to another solar powered base to drive it illuminating simultaneously. Each solar powered base further has a timing device; if the sensor is not induced again, or the transceiver does not receive any signal from another base at a predetermined interval, the power of the at least one first illumination device will be cut off to save electric energy. Each solar powered base still further has at least one second illumination device to provide basic illumination continually in the evening.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

Aspects of the present invention are illustrated, merely by way of example, in the accompanying drawings in which:

FIG. 1 is a perspective view of a solar powered base according to the present invention; and

FIG. 2 is a schematic view of a solar powered base according to the present invention.

### DETAILED DESCRIPTION OF THE PREFFERED EMBODIMENT

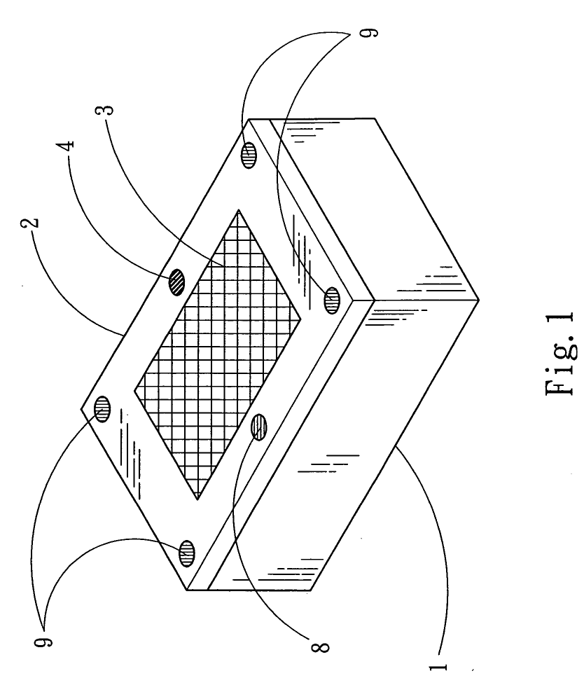

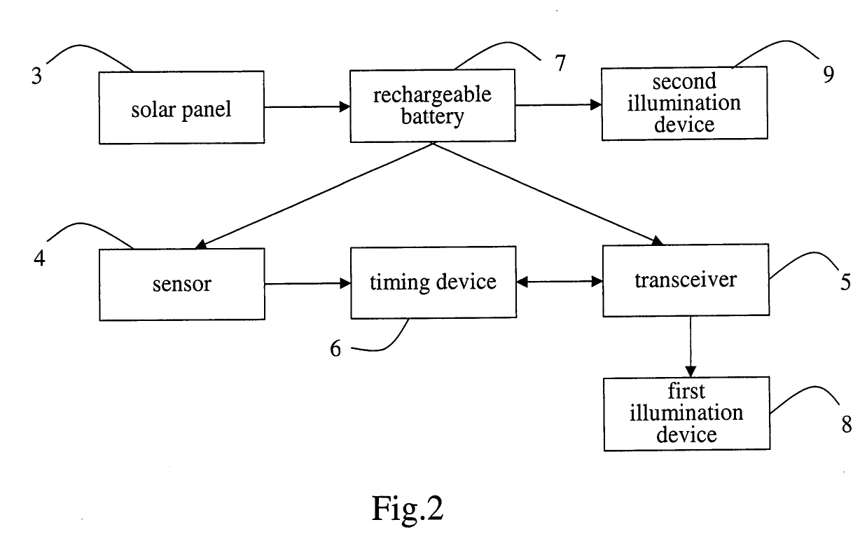

With reference to FIG. 1 and FIG. 2, FIG. 1 is a perspective view of a solar powered base according to the present invention, and FIG. 2 is a schematic view of a solar powered base according to the present invention. The present invention relates to a base assembly having a plurality of solar powered illuminators. The shape of the solar powered base of the preferred embodiment according to the invention is a rectangular solid, but other shape of a cubic solid, a regular polygon solid, a polygon solid, or a cylinder is also acceptable. The accompany drawings are just exemplary and explanatory but not to be restrictive of the shape of the present invention.

The solar powered base essentially comprises a pedestal 1; a cover 2; a solar panel 3; a sensor 4 (such as an infrared sensor, a photoelectric sensor, a thermal radiation sensor, a sound wave sensor, or a motion sensor); a transceiver 5 (such as a wireless transceiver); a timing device 6 (such as a circuit board, or an integrated circuit chip); a rechargeable battery 7; first illumination devices 8 (such as light bulbs, light-emitting diodes, or laser devices); and at least one second illumination device 9 (such as a light bulb, a light-emitting diode, or a laser device).

The cover 2, on the surface of which are disposed the first illumination devices 8, the at least one second illumination device 9, and a sensor 4, is securely mounted on top of the pedestal 1, wherein the first illumination devices 8 and the sensor 4 are electrically connected to the rechargeable battery 7. The solar panel 3 is set up on the surface of the cover 2, and its surface is mantled with a firm and solid transparent body (not shown in the figure) for protection and anti-pollution. The solar panel 3 is able to collect solar energy, converts the solar energy to electric energy, and charges the rechargeable battery 7. In the evening or in the dark place, when the solar panel 3 stops collecting solar energy, the rechargeable battery 7 automatically discharges electricity to all elements provided with base to utilize. Additionally, the solar powered base further has a timing device 6, which is respectively electrically connected to the transceiver 5 and the sensor 4. When a person or an object induces the sensing of the sensor 4, the timing device 6 starts counting time and the sensor 4 sends a signal through the transceiver 5 to the first illumination devices 8 immediately to drive them illuminating. At the same time, the transceiver 5 also sends a signal to another solar powered base, and when another solar powered base receives the signal by its transceiver 5, the transceiver 5 also sends a signal to its first illumination devices 8 to drive them simultaneously illuminating. If predetermined interval has passed, and the sensor 4 has not been induced again, or the transceiver 5 has not receive any signal sent from another solar powered base, the power of the first illumination devices 8 is automatically cut off to save energy. In each solar powered base, the at least one second illumination device 9 selectively provides basic illumination continually in the evening or in the dark place.

Accordingly, the present invention of simultaneously illuminated solar powered base assembly can be installed in the public place, big shopping mall, amusement park, tourist spots, garden and courtyard etc. to provide illumination and save energy, and further to give a fascinating atmosphere.

Although the present invention has been described in some detail by way of example for purposes of clarity and understanding, it will be apparent that certain chances and modifications may be practiced within the scope of the appended claims.

What is claimed is:

1. A solar powered base comprising:
a pedestal having at least one rechargeable battery;
a cover securely mounted on top of the pedestal;
a solar panel electrically connected to the rechargeable battery for collection of solar energy so as to convert the solar energy to electric energy to charge the rechargeable battery;
a sensor electrically connected to the rechargeable battery for sensing ambient situation and selectively sending a signal; and
at least one illumination device provided on the pedestal, and respectively electrically connected to the rechargeable battery and the sensor to receive the signal from the sensor to emit a light through the pedestal.

2. A solar powered base as claimed in claim 1, wherein the base further has a timing device electrically connected to the sensor and the at least one illumination device to determine the illuminating time of the at least one illumination device.

3. A solar powered base as claimed in claim 1, wherein the base is a floor brick.

4. A solar powered base as claimed in claim 1, wherein the way of the sensing is one of follows: infrared sensing, photoelectric sensing, thermal radiation sensing, sound wave sensing, motion sensing.

5. A solar powered base as claimed in claim 1, wherein the at least one illumination device is one of follows: light bulb, light-emitting diode (LED), laser.

6. A solar powered base as claimed in claim 2, wherein the timing device is one of follows: printed circuit board, integrated circuit chip.

7. A solar powered base comprising:
a pedestal having at least one rechargeable battery;
a cover securely mounted on top of the pedestal;
a sensor electrically connected to the rechargeable battery for sensing ambient situation and selectively sending a signal;
a solar panel electrically connected to the rechargeable battery for collection of solar energy so as to convert the solar energy to electrical energy to charge the rechargeable battery; and
a transceiver respectively electrically connected to the rechargeable battery and the sensor to receive the signal from the sensor, and simultaneously sending a signal to at least one illumination device, wherein the at least one illumination device is provided on the pedestal, and respectively electrically connected to the rechargeable battery and the transceiver to receive the signal to emit a light through the pedestal.

8. A solar powered base as claimed in claim 7, wherein the base further has a timing device electrically connected to the sensor and the transceiver to determine the illuminating time of the at least one illumination device.

9. A solar powered base as claimed in claim 7, wherein the base is a floor brick.

10. A solar powered base as claimed in claim 7, wherein the way of the sensing is one of follows: infrared sensing, photoelectric sensing, thermal radiation sensing, sound wave sensing, motion sensing.

11. A solar powered base as claimed in claim 7, wherein the at least one illumination device is one of follows: light bulb, light-emitting diode (LED), laser.

12. A solar powered base as claimed in claim 7, wherein the transceiver is a wireless transceiver.

13. A solar powered base as claimed in claim 8, wherein the timing device is one of follows: printed circuit board, integrated circuit chip.

14. A solar powered base as claimed in claim 7, wherein the solar powered base further has at least one second illumination device electrically connected to rechargeable battery to provide a basic illumination continually.

15. A solar powered base as claimed in claim 14, wherein the at least one second illumination device is one of follows: light bulb, light-emitting diode (LED), laser.
